(19) United States
(12) Patent Application Publication
(10) Pub. No.: US 2010/0230721 A1
(43) Pub. Date: Sep. 16, 2010

(54) SEMICONDUCTOR DEVICE AND MANUFACTURING METHOD OF SEMICONDUCTOR DEVICE

(75) Inventor: Nobuaki YASUTAKE, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/723,806

(22) Filed: Mar. 15, 2010

(30) Foreign Application Priority Data
Mar. 13, 2009 (JP) 2009-061717

(51) Int. Cl. H01L 29/772; H01L 21/336

(52) U.S. Cl. 257/192; 438/197; 257/347; 257/288; 257/E21.4; 257/E29.242

(57) ABSTRACT

In one aspect of the present invention, a semiconductor device may include a gate electrode formed on a gate insulation film on a main surface of a semiconductor substrate of a first conductivity type; source/drain regions formed to sandwich a channel region formed below the gate electrode, the source/drain regions having a structure in which a first semiconductor layer and a second semiconductor layer are stacked in this order, the first semiconductor layer containing a first element and an impurity of a second conductivity type that are forgiving strain to the channel region, and containing a second element that is for suppressing a diffusion of the impurity of the second conductivity type, the second semiconductor layer containing the first element and the impurity of the second conductivity type; and source/drain extension regions adjacent to the channel region, the extension regions extending respectively from the second semiconductor layers.

### CROSS REFERENCE TO RELATED APPLICATION

This application is based upon and claims the benefit of priority from Japanese Patent Application No. 2009-61717, filed on Mar. 13, 2009, the entire contents of which are incorporated herein by reference.

### BACKGROUND

There is known a higher-performance semiconductor device that has carrier mobility improved in such a way that a crystal having a lattice constant different from that of a silicon (Si) crystal is buried in source/drain regions, and that a channel region is given a strain by taking advantage of the difference between the lattice constants (see, for example, JP2006-13428A).

The semiconductor device disclosed in JP2006-13428A includes compression stress applying portions, which are made of SiGe films formed in the source/drain regions of the PMOS region by the chemical vapor deposition (CVD) method. The semiconductor device also includes shallow junction regions and deep junction regions formed by the ion implantation method.

In this regard, the shallow junction regions and the deep junction regions are formed after the formation of the compression stress applying portions. For this reason, impurities in the shallow junction regions can be prevented from diffusing immediately below the gate insulation film, although such diffusion would otherwise occur due to the heating during the formation of the SiGe films. Thus, the short channel effect is prevented.

In the semiconductor device disclosed in JP2006-13428A, however, boron (B), which is a p-type impurity, has to be doped into the SiGe film so as to reduce the parasitic resistance.

With miniaturization and higher performance of semiconductor devices, higher compression stress is required to be applied to the channel region. Accordingly, in semiconductor devices of newer generations, the SiGe film is formed more closely to the channel region.

However, when the SiGe film is formed more closely to the channel region, there is a problem that diffusion of boron from the SiGe film deteriorates the short channel characteristics. Consequently, it becomes difficult to achieve both of higher mobility of holes and good short channel characteristics.

### SUMMARY

Aspects of the invention relate to an improved semiconductor device and a manufacturing method of a semiconductor device.

In one aspect of the present invention, a semiconductor device may include a gate electrode formed on a gate insulation film on a main surface of a semiconductor substrate of a first conductivity type; source/drain regions formed to sandwich a channel region formed below the gate electrode, the source/drain regions having a structure in which a first semiconductor layer and a second semiconductor layer are stacked in this order, the first semiconductor layer containing a first element and an impurity of a second conductivity type that are for giving strain to the channel region, and containing a second element that is for suppressing a diffusion of the impurity of the second conductivity type, the second semiconductor layer containing the first element and the impurity of the second conductivity type; and source/drain extension regions adjacent to the channel region, the extension regions extending respectively from the second semiconductor layers.

In another aspect of the invention, method of manufacturing a semiconductor device may include: forming a gate electrode on a gate insulation film on a main surface of a semiconductor substrate of a first conductivity type; forming recessed portions by removing the semiconductor substrate partly at both sides of the gate electrode; forming source/drain regions by stacking a first semiconductor layer and a second semiconductor layer in this order in each of the recessed portions, the source/drain regions sandwiching the channel region formed below the gate electrode, the first semiconductor layer containing a first element and an impurity of a second conductivity type that are for giving strain to the channel region, and also containing a second element that is for hampering diffusion of the impurity of the second conductivity type, the second semiconductor layer containing the first element and the impurity of the second conductivity type; forming source/drain extension regions adjacent to the channel region, by diffusing the impurity of the second conductivity type contained in the second semiconductor layers towards the gate electrode through heat treatment on the semiconductor substrate.

### BRIEF DESCRIPTIONS OF THE DRAWINGS

A more complete appreciation of the invention and many of the attendant advantages thereof will be readily obtained as the same becomes better understood by reference to the following detailed description when considered in connection with the accompanying drawings.

FIG. 1 is a sectional diagram illustrating a semiconductor device.

FIG. 2 is a chart illustrating a comparison of characteristics between the semiconductor device of the first embodiment and a semiconductor device of a comparative example.

FIG. 3 is a sectional diagram illustrating the semiconductor device of the comparative example.

FIGS. 4 to 7 are sectional diagrams sequentially illustrating processes of manufacturing the semiconductor device.

FIG. 8 is a sectional diagram illustrating a semiconductor device of a second embodiment.

FIGS. 9 to 11 are sectional diagrams sequentially illustrating processes of manufacturing the semiconductor device.

### DETAILED DESCRIPTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as next described, wherein like reference numerals designate identical or corresponding parts throughout the several views.

### First Embodiment

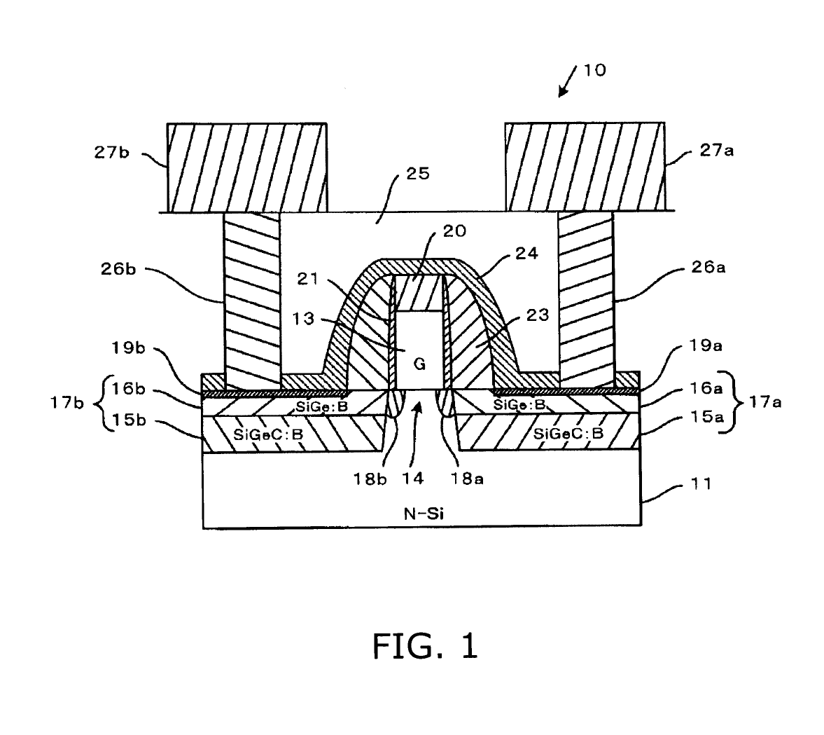

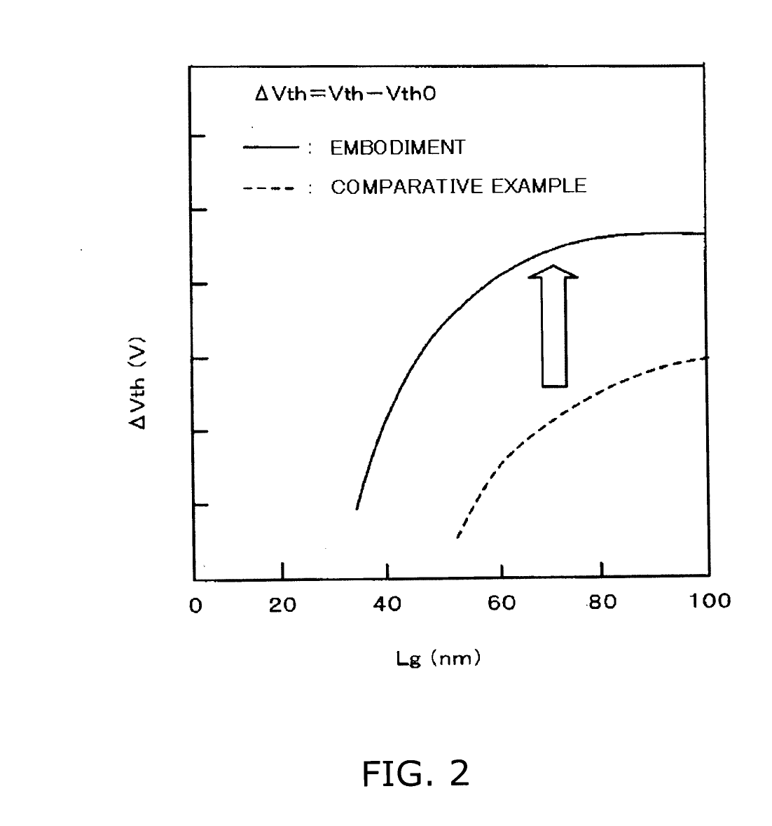

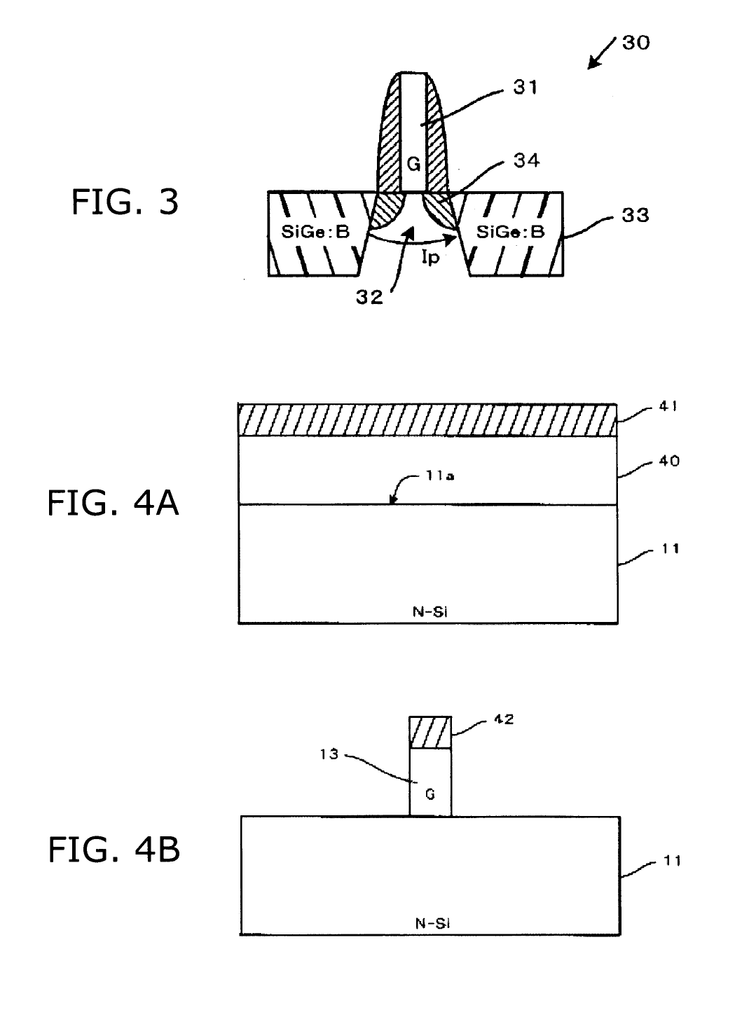

A semiconductor device and a method of manufacturing the semiconductor device according to The first embodiment will be described by referring to FIGS. 1 to 7. FIG. 1 is a sectional diagram illustrating a semiconductor device. FIG. 2 is a chart illustrating a comparison of characteristics between the semiconductor device of the first embodiment and a semiconductor device of Comparative Example. In FIG. 2, the characteristics of the first embodiment are represented by the solid line, whereas the characteristics of Comparative Example are represented by the dashed line. FIG. 3 is a sectional diagram illustrating the semiconductor device of Comparative Example. FIGS. 4 to 7 are sectional diagrams sequentially illustrating processes of manufacturing the semiconductor device.

As FIG. 1 shows, a semiconductor device 10 of the first embodiment includes: a gate electrode 13; source/drain regions 17a, 17b; and extension (extremely shallow junction) regions 18a, 18b. The gate electrode 13 is formed on an unillustrated gate insulation film on a main surface of an n-type (first conductivity type) silicon substrate (semiconductor substrate) 11. The source/drain region 17a has a structure in which layers of a first semiconductor layer 15a and a second semiconductor layer 16a are formed in this order on the silicon substrate 11, whereas the source/drain region 17b has a structure in which layers of a first semiconductor layer 15b and a second semiconductor layer 16b are formed in this order on the silicon substrate 11. A channel region 14 is formed under the gate electrode 13, and the source/drain regions 17a, 17b are formed so as to sandwich the channel region 14. The first semiconductor layers 15a, 15b contain: germanium (Ge: first element), which gives strain to the channel region 14; boron (B), which is a p-type (second conductivity type) impurity; and carbon (C: second element), which prevents diffusion of boron. The second semiconductor layers 16a, 16b contain germanium and boron. Each of the extension regions 18a, 18b extends from a sidewall of the corresponding one of the second semiconductor layers 16a, 16b. The above-mentioned sidewall is the one located near the gate electrode 13. The extension regions 18a, 18b are formed adjacent to the channel region 14 .

The first semiconductor layers 15a, 15b are mixed crystal semiconductor layers containing silicon, germanium, and a small amount of carbon. In addition, boron is added by an amount ranging from 10¹⁸ to 10²¹ cm⁻³ so as to give p-type conductivity to the first semiconductor layers 15a, 15b and to reduce the parasitic resistance. Accordingly, the first semiconductor layers 15a, 15b are Si_{(1-x-y)}GeₓC_{y}:B.

The second semiconductor layers 16a, 16b are mixed crystal semiconductor layers containing silicon and germanium. In addition, boron is added by an amount ranging from 10¹⁸ to 10²¹ cm⁻³ so as to give p-type conductivity to the second semiconductor layers 16a, 16b and to reduce the parasitic resistance. Accordingly, the second semiconductor layers 16a, 16b are Si_{(1-z)}Ge_{z}:B.

The lattice constant of SiGe is larger than that of Si. Accordingly, the second semiconductor layers 16a, 16b are capable of giving compression strain to the channel region 14, and thereby enhancing the mobility of holes in the channel region 14.

The lattice constant of SiGeC is larger than that of Si. Accordingly, the first semiconductor layers 15a, 15b are capable of giving compression strain to the channel region 14, and thereby enhancing the mobility of holes in the channel region 14. The lattice constant of SiGeC, however, is smaller than that of SiGe. Accordingly, SiGeC has a smaller effect of giving compression strain to the channel region 14 than SiGe.

The concentration x of germanium in the first semiconductor layers 15a, 15b and the concentration z of germanium in the second semiconductor layers 16a, 16b are preferably within a range from approximately 10 to 30 atom %. Too low Ge concentration makes the compression strain to be given to the channel region 14 insufficient. Too high Ge concentration leads to crystal defects, which may cause leakage current.

The concentration y of carbon in the first semiconductor layers 15a, 15b is preferably higher than 0 atom % and lower than 1 atom %. If the C concentration in the first semiconductor layers 15a, 15b is 0 atom %, the effect of preventing the diffusion of boron cannot be obtained. Too high C concentration reduces the effect of giving compression strain to the channel region 14, and leads to crystal defects, which may cause leakage current.

The extension regions 18a, 18b are formed by diffusing boron from sidewalls of the second semiconductor layers 16a, 16b. The above-mentioned sidewalls are located near the gate electrode 13. The process of forming the extension regions 18a, 18b will be described in detail later. The extension regions 18a, 18b form parts of source/drain.

Boron is diffused isotropically. Accordingly, the bottom-end portions of the extension regions 18a, 18b reach deeper positions in the silicon substrate 11 than the portions where the extension regions 18a, 18b are in contact respectively with the gate electrode 13 side sidewalls of the second semiconductor layers 16a, 16b.

An insulation film 21 is formed on a sidewall film 23 on the sidewall of the gate electrode 13. The second semiconductor layers 16a, 16b and the gate electrode 13 are covered with a silicon nitride film 24.

Vias 26a, 26b are formed so as to penetrate through an interlayer insulation film 25. The source/drain region 17a is connected to a wiring 27a by means of the via 26a, whereas the source/drain region 17b is connected to a wiring 27b by means of the via 26b.

Silicide layers 19a, 19b are formed respectively on the second semiconductor layers 16a, 16b. For example, each of the silicide layers 19a, 19b has a thickness of approximately 20 nm. A silicide layer 20 is formed on the gate electrode 13. For example, the silicide layer 20 has a thickness of approximately 20 nm.

The silicide layer 19a is formed to decrease the contact resistance between the source/drain region 17a and the via 26a, whereas the silicide layer 19b is formed to decrease the contact resistance between the source/drain region 17b and the via 26b. The silicide layer 20 is formed to decrease the contact resistance between the gate electrode 13 and an unillustrated gate wiring.

FIG. 2 is a chart (conceptual chart) illustrating the relationship between the gate length Lg of and the shift amount ΔVth of threshold. FIG. 2 compares the above-mentioned relationship of the semiconductor device of the first embodiment with that of a semiconductor device of Comparative Example. The solid line in FIG. 2 represents the characteristics of the semiconductor device of the first embodiment, whereas the dashed line represents the characteristics of the semiconductor device of Comparative Example. The shift amount ΔVth of threshold in FIG. 2 represents a shift amount from the threshold Vth0 in the case where the gate length Lg is sufficiently large.

The above-mentioned semiconductor device of Comparative Example is a semiconductor device having source/drain regions in which boron-doped SiGe film is buried. Description of Comparative Example will be given first.

As FIG. 3 shows, a semiconductor device 30 includes a gate electrode 31, source/drain regions 33, and extension regions 34. The gate electrode 31 is formed on an unillustrated gate insulation film on an unillustrated silicon substrate. The source/drain regions 33 are formed so as to sandwich the gate electrode 31. A SiGe film to give compression strain to a channel region 32 is buried in the source/drain regions 33. The extension regions 34 are shallower than the source/drain regions 33, and are formed adjacent to the channel region 32.

The source/drain regions 33 are doped with boron so as to give p-type conductivity and to reduce the parasitic resistance of the SiGe film. The extension regions 34 are formed by implanting ions of boron.

As FIG. 2 shows, in the case of the semiconductor device 30, as the gate length Lg becomes shorter, the threshold Vth shifts in the negative direction and the short channel characteristics are deteriorated.

The worsening of the short channel characteristics occurs for the following reason. As the gate length Lg becomes shorter, the influence of boron diffused from the SiGe film becomes unignorable. The unignorable influence of boron diffusion causes the punch-through effect, in which a current Ip that uncontrollable by the gate flows below the channel region 32.

In contrast, in the case of the semiconductor device 10 of the first embodiment, until the gate length Lg reaches down a certain value, a shift amount ΔVth of threshold is small, and thus the deterioration of the short channel characteristics is ignorable. It is certain that if the gate length Lg reaches down a certain value or even lower, the shift amount ΔVth of threshold becomes unignorable, but the shift amount ΔVth of threshold is still smaller than that of the Comparative Example.

This is because though boron is diffused from the second semiconductor layers 16a, 16b of SiGe:B, no boron is diffused from the first semiconductor layers 15a, 15b of SiGeC:B.

In other words, the semiconductor device 10 is capable of controlling the amount of boron diffusion and the distribution of the diffused boron. While the extension regions 18a, 18b are formed by the boron diffused from the second semiconductor layers 16a, 16b, the diffusion of boron to the area below the channel region 14 can be prevented. Accordingly, the extension regions 18a, 18b can be formed without an ion-implantation process of boron.

Subsequently, description will be given of a method of manufacturing the semiconductor device 10. FIGS. 4 to 7 are sectional diagrams sequentially illustrating processes of manufacturing the semiconductor device 10.

As FIG. 4A shows, a silicon oxide film (not illustrated) is formed as a gate insulating film on a main surface 11a of the n-type silicon substrate 11 by the thermal oxidation method, and then a polysilicon film 40 is formed on the gate insulating film by, for example, the chemical vapor deposition (CVD) method.

Subsequently, a silicon oxide film (not illustrated) is formed on the polysilicon film 40 by, for example, the CVD method. Then, a silicon nitride film 41 is formed on the silicon oxide film by, for example, the plasma CVD method.

Subsequently, as FIG. 4B shows, a process of patterning the silicon nitride film 41 is performed so as to form a mask material 42 having a pattern corresponding to a gate electrode 13. Then, using the mask material 42, the polysilicon film 40 is etched by the RIE method so as to form the gate electrode 13.

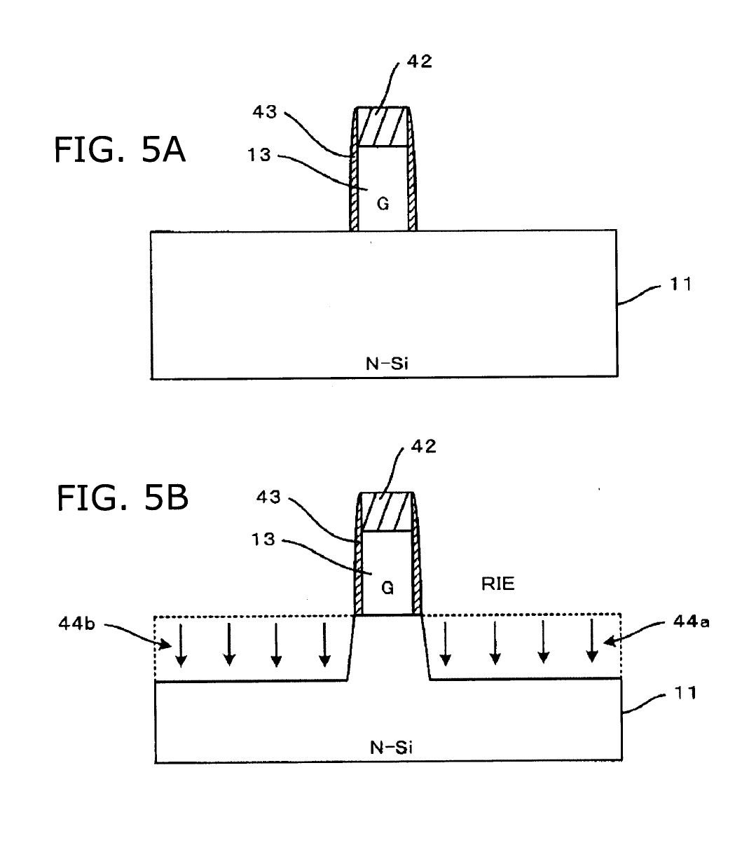

Subsequently, as FIG. 5A shows, in order to remove the damage on the sidewall of the gate electrode 13, post-gate oxidation is performed by the thermal oxidation method. Then, a silicon nitride film with a thickness of approximately 10 nm, is formed by the CVD method.

Subsequently, the silicon nitride film is etched by the RIE method, and silicon nitride film is left on the sidewall of the gate electrode 13. The silicon nitride film left on the sidewall of the gate electrode 13 is an insulation film 43.

Subsequently, as FIG. 5B shows, using the mask material 42 and the insulation film 43 as masks, the silicon substrate 11 is dug down by the RIE method so as to form recessed portions 44a, 44b. Each of the recessed portions 44a, 44b has at least a depth deep enough to saturate the compression strain given to a channel region 14. For example, an appropriate depth of each of the recessed portions 44a, 44b ranges from approximately 80 to 100 nm.

Note that each of the recessed portions 44a, 44b are surrounded by an element separation layer (not illustrated), such as a shallow trench isolation (STI) layer. The region other than the recessed portions 44a, 44b is covered with a silicon oxide film (not illustrated).

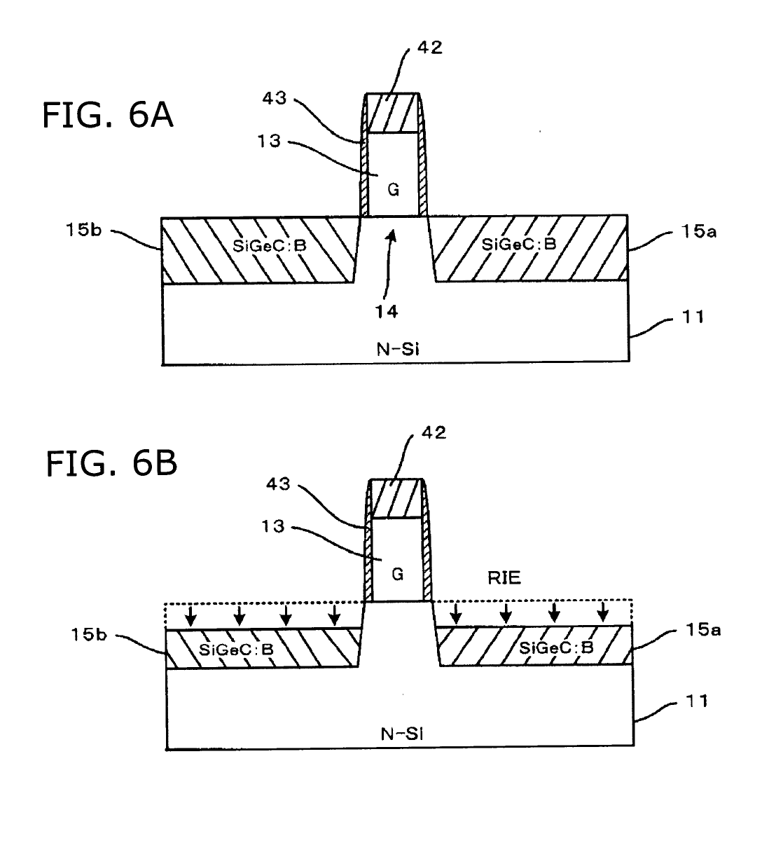

Subsequently, as FIG. 6A shows, carbon-added, boron-doped SiGe crystals (SiGeC:B) are grown selectively and epitaxially in the recessed portions 44a, 44b of the silicon substrate 11. Thereby, the first semiconductor layers 15a, 15b are buried respectively in the recessed portions 44a, 44b.

Specifically, SiGeC:B is grown epitaxially by the low pressure CVD (LPCVD) method at a temperature in a range from 700° C. to 800° C. Here, hydrogen (H2) gas is used as the carrier gas; gasses of monosilane (SiH4), germane (GeH4), and acetylene (C2H2) are used as the process gasses; and diborane (B2H2) gas is used as the dopant gas. Epitaxial growth of SiGeC occurs only on silicon, and no deposition of SiGeC occurs on the silicon oxide film. Consequently, selective epitaxial growth can take place.

Subsequently, as FIG. 6B shows, the first semiconductor layers 15a, 15b are dug, by the RIE method, down to a depth that allows the extension regions 18a, 18b to be formed in the space thus formed. Consequently, the sidewalls of the recessed portions 44a, 44b are exposed.

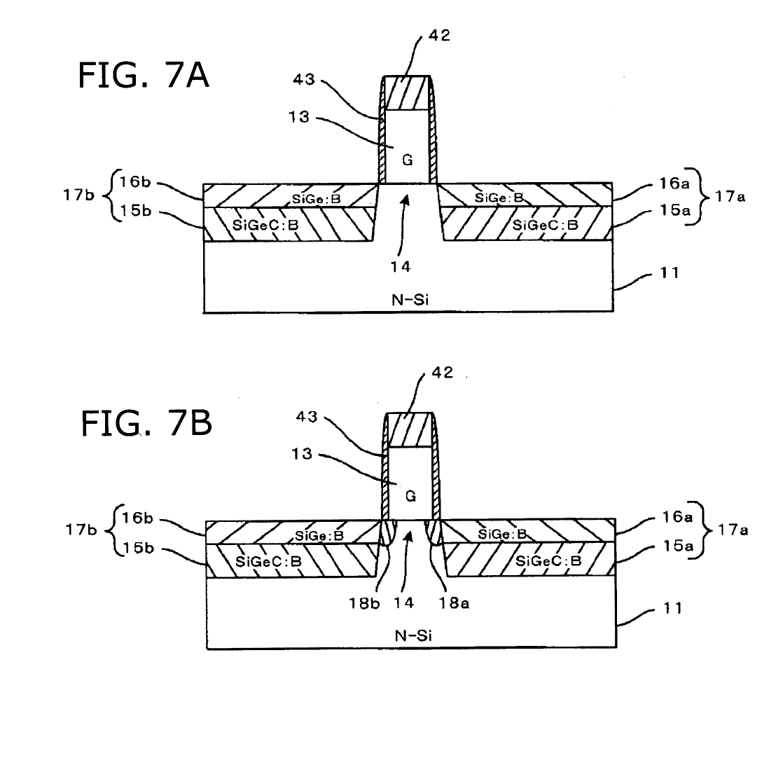

Subsequently, as FIG. 7A shows, boron-doped SiGe crystals (SiGe:B) are grown selectively and epitaxially on the first semiconductor layers 15a, 15b. Thus, the second semiconductor layers 16a, 16b are buried respectively in the recessed portions 44a, 44b. Thus, the source/drain regions 17a, 17b are formed.

Subsequently, as FIG. 7B shows, a heat treatment is performed at, for example, 1000° C. by the rapid thermal annealing (RTA) method so as to repair the crystal defects in the SiGe film and the SiGeC film after the selective epitaxial growth, and to diffuse the boron in the second semiconductor layers 16a, 16b. Thus, the extension regions 18a, 18b, which extend respectively from the gate electrode 13 side sidewalls of the second semiconductor layers 16a, 16b, are formed adjacent to the channel region 14.

Subsequently, the mask material 42 and the insulation film 43 are removed, and then a sidewall film 23 is formed on an insulating film 21 that has been formed on the sidewall of the gate electrode 13. In addition, silicide layers 19a, 19b each of which has, for example, an approximately 20-nm thickness are formed respectively on the second semiconductor layers 16a, 16b. A silicide layer 20 which has, for example, an approximately 20-nm thickness is formed on the gate electrode 13.

Subsequently, a silicon nitride film 24 is formed so as to cover the gate electrode 13 and the second semiconductor layers 16a, 16b. In addition, an interlayer insulation film 25 is formed to cover the entire surfaces of the silicon substrate 11.

Subsequently, contact holes are formed in the interlayer insulation film 25. Conductive materials are buried in the contact holes, and thus formed are vias 26a, 26b.

Subsequently, wirings 27a, 27b are formed on the interlayer insulation film 25. The wiring 27a is connected to the source/drain region 17a by means of the via 26a, whereas the wiring 27b is connected to the source/drain region 17b by means of the via 26b. Thus obtained is the semiconductor device 10 shown in FIG. 1.

As has been described thus far, the semiconductor device 10 of the first embodiment includes the source/drain regions 17a, 17b formed so as to sandwich the channel region 14, which is formed under the gate electrode 13. The source/drain region 17a has a structure in which layers of the first semiconductor layer 15a and the second semiconductor layer 16a are formed in this order, whereas the source/drain region 17b has a structure in which layers of the first semiconductor layer 15b and the second semiconductor layer 16b are formed in this order. The first semiconductor layers 15a, 15b contain: germanium, which gives strain to the channel region 14; boron, which gives strain to the channel region 14; and carbon, which prevents the diffusion of boron. The second semiconductor layers 16a, 16b contain germanium and boron.

As a consequence, the first semiconductor layers 15a, 15b and the second semiconductor layers 16a, 16b give sufficient compression strain to the channel region 14. In addition, the diffusion of boron from the first semiconductor layers 15a, 15b is prevented while diffusion of boron is allowed from the second semiconductor layers 16a, 16b. Accordingly, the amount of boron diffusion from the source/drain regions 17a, 17b and the distribution of boron can be controlled.

Accordingly, the extension regions 18a, 18b can be formed by the boron diffused from the second semiconductor layers 16a, 16b while the diffusion of boron below the channel region 14 can be prevented. Thereby, occurrence of a punch-through effect, in which a current Ip uncontrollable by the gate flows below the channel region 14, can be reduced.

Thus obtained is a semiconductor device including source/drain regions which has semiconductor layers buried therein and is capable of causing sufficient strain in the channel region without deteriorating the short channel characteristics. In addition, a manufacturing method of the semiconductor device can be obtained as well.

The description having been given thus far is based on a case where the silicon substrate 11 is an n-type bulk silicon substrate, but the silicon substrate 11 may be an n-type well layer formed on a silicon substrate. In addition, the substrate on which the n-type well layer is formed may be a silicon-on-insulator (SOI) substrate.

In addition, in the above-described case, the source/drain regions 17a, 17b are formed by: burying the SiGeC films in the recessed portions 44a, 44b; then etching the SiGeC films halfway; and then burying the SiGe films. Alternatively, the source/drain regions 17a, 17b may be formed by forming the SiGeC films and the SiGe films consecutively.

If the SiGeC films and the SiGe films are formed consecutively, it is necessary to consider the growth conditions better than in the case where the SiGeC films and the SiGe films are formed separately. For example, the growth conditions has to be set so as to prevent the SiGeC films from being formed on the upper-side portions of the sidewalls of the recessed portions 44a, 44b.

This is because if the SiGeC films are grown on the upper-side portions of the sidewalls, the diffusion of boron from the SiGe film is hampered and thereby the formation of the extension regions 18a, 18b is obstructed.

Comparative Example employed in the foregoing description is the semiconductor device including source/drain regions in which boron-doped SiGe films are buried. If a semiconductor device including source/drain regions in which boron-doped SiGeC films are buried is employed instead, the use of such a semiconductor device causes such problems as follows. It is more difficult to give sufficient compression strain to the channel region 14. The extension regions 18a, 18b have to be formed by ion plantation, which requires more manufacturing processes.

In the above-described case, the Si process gas and the C process gas that are used in the epitaxial growth of the SiGe films and the SiGeC films are respectively the monosilane (SiH₄) and acetylene (C₂H₂). Alternatively, disilane (Si₂H₆), Trimethylsilane ((CH₃)₃SiH), ethylene (C₂H₄), and the like may be used instead.

### Second Embodiment

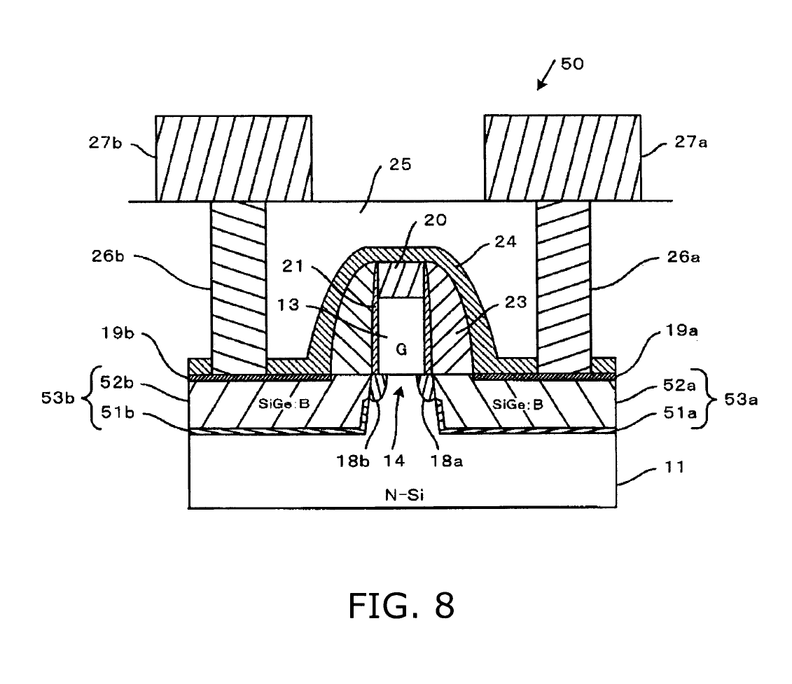

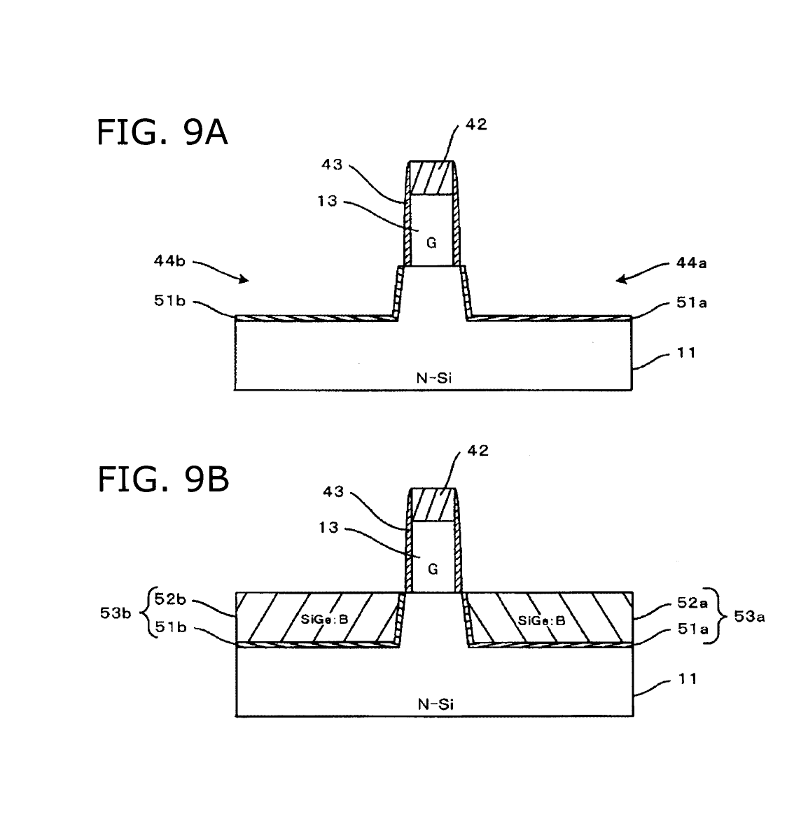

A semiconductor device according to the second embodiment will be described by referring to FIGS. 8 to 11. FIG. 8 is a sectional diagram illustrating a semiconductor device of the second embodiment. FIGS. 9 to 11 are sectional diagrams sequentially illustrating processes of manufacturing the semiconductor device.

In The second embodiment, the same constituent portions as those in the first embodiment are denoted by the same reference numerals. Such constituent portions will not be described in the following description. The following description concerns only the portions that are different from the configuration of the first embodiment. The point that distinguishes the second embodiment from the first embodiment is that each of the first semiconductor layers in the second embodiment has a smaller volume than the corresponding volume in the first embodiment, and each of the second semiconductor layers in the second embodiment has a larger volume than the corresponding volume in the first embodiment.

As FIG. 8 shows, a semiconductor device 50 of the second embodiment includes source/drain regions 53a, 53b including: first semiconductor layers 51a, 51b; and second semiconductor layers 52a, 52b. Each of the first semiconductor layers 51a, 51b has a thickness of approximately several nanometers. The first semiconductor layers 51a, 51b are formed to cover bottom surfaces of unillustrated recessed portions 44a, 44b and to cover portions of the sidewalls of the recessed portions 44a, 44b. The portions that covered are from the bottom surface up to the positions reached by extension regions 18a, 18b to be formed (hereafter, the portions will be referred to as the “lower-side sidewalls”). The second semiconductor layers 52a, 52b are formed on the first semiconductor layers 51a, 51b so as to fill the recessed portions 44a, 44b.

The second semiconductor layers 52a, 52b are in contact with portions of sidewalls of a silicon substrate 11. The portions that are in contact with the second semiconductor layers 52a, 52b are from the main surface of the silicon substrate 11 up to positions reached by the extension regions 18a, 18b to be formed (hereafter, the portions will be referred to as the “upper-side sidewalls”).

With this configuration, the volume of each of the first semiconductor layers 51a, 51b is decreased sufficiently. On the other hand, the volume of each of the second semiconductor layers 52a, 52b is increased sufficiently. Note that the second semiconductor layers 52a, 52b have a lattice constant that is larger than the lattice constant of the first semiconductor layers 51a, 51b. Accordingly, the compression strain to be given to a channel region 14 becomes larger than otherwise.

As a consequence, the mobility of holes is enhanced further. Accordingly, an improvement in characteristics of the semiconductor device 50 can be achieved without deteriorating the short channel characteristics.

Subsequently, description will be given concerning a method of manufacturing the semiconductor device 50. FIGS. 9 to 11 are sectional diagrams sequentially illustrating processes of manufacturing the semiconductor device 50.

First of all, in a manner shown in FIG. 5A, the recessed portions 44a, 44b are formed by digging the silicon substrate 11.

Subsequently, as FIG. 9A shows, carbon-added, boron-doped SiGeC crystals (SiGeC:B) are grown selectively and epitaxially in the recessed portions 44a, 44b of the silicon substrate 11. The thickness of the boron-doped SiGeC crystals thus grown is approximately several nanometers. Thus formed are the first semiconductor layers 51a, 51b.

The crystals of SiGeC are grown only the regions where silicon is exposed, so that the bottom surfaces and the sidewalls of the recessed portions 44a, 44b are covered with the crystals of SiGeC.

Subsequently, as FIG. 9B shows, boron-doped SiGe crystals (SiGe:B) are grown selectively and epitaxially on the first semiconductor layers 51a, 51a. Thus, the recessed portions 44a, 44b are filled respectively with the second semiconductor layers 52a, 52b.

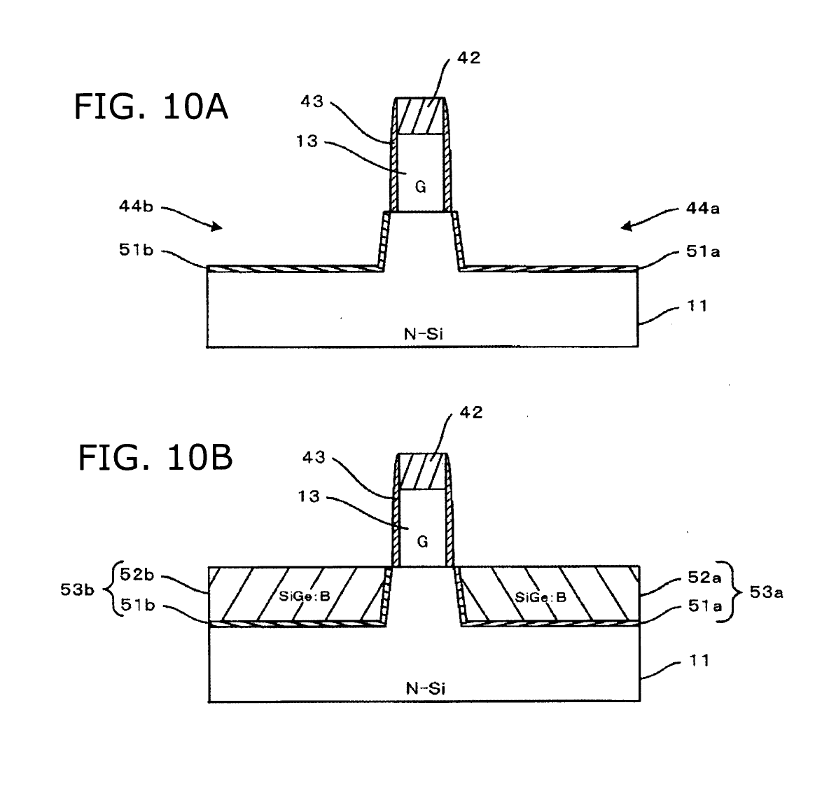

Subsequently, as FIG. 10A shows, the second semiconductor layers 52a, 52b and the first semiconductor layers 51a, 51b that covers respectively the sidewalls of the recessed portions 44a, 44b are dug, by the RIE method, down to a depth that allows the extension regions 18a, 18b to be formed in the space thus formed. Consequently, the upper-side sidewalls of the recessed portions 44a, 44b are exposed.

Subsequently, as FIG. 10B shows, boron-doped SiGe crystals (SiGe:B) are grown selectively and epitaxially on the second semiconductor layers 52a, 52b. Thus, the recessed portions 44a, 44b are filled respectively with the additionally-formed second semiconductor layers 52a, 52b. Thus formed are the source/drain regions 53a, 53b.

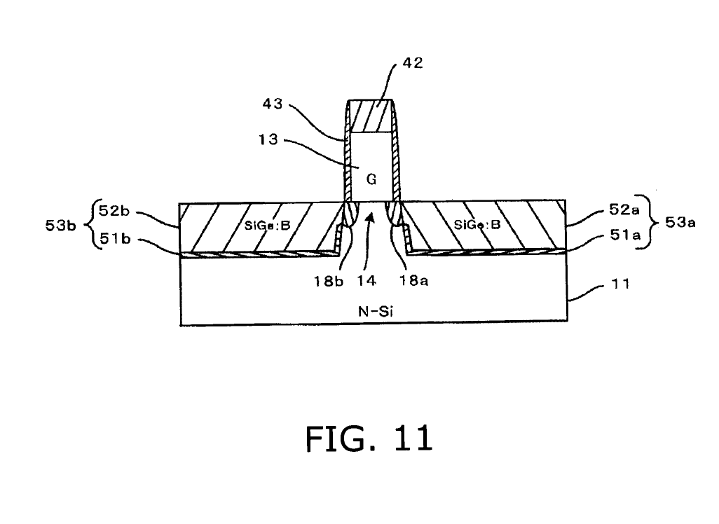

Subsequently, as FIG. 11 shows, a heat treatment is performed by the RTA method so as to diffuse the boron in the second semiconductor layers 52a, 52b. Thus, the extension regions 18a, 18b, which extend respectively from the gate electrode 13 side sidewalls of the second semiconductor layers 52a, 52b, are formed adjacent to the channel region 14.

As has been described thus far, the semiconductor device 50 of the second embodiment includes: the first semiconductor layers 51a, 51b; and the second semiconductor layers 52a, 52b. The first semiconductor layers 51a, 51b are formed to cover bottom surfaces of the recessed portions 44a, 44b and to cover the lower-side sidewalls of the recessed portions 44a, 44b. The second semiconductor layers 52a, 52b are formed on the first semiconductor layers 51a, 51b so as to fill the recessed portions 44a, 44b. Each of the first semiconductor layers 51a, 51b in the second embodiment has a smaller volume than the corresponding volume in the first embodiment, whereas each of the second semiconductor layers 52a, 52b in the second embodiment has a larger volume than the corresponding volume in the first embodiment.

Accordingly, the compression strain to be given to a channel region 14 becomes larger than otherwise. As a consequence, the semiconductor device 50 of the second embodiment has an advantage of improving the characteristics of the semiconductor device 50 without deteriorating the short channel characteristics.

Embodiments of the invention have been described with reference to the examples. However, the invention is not limited thereto.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

What is claimed is:

1. A semiconductor device comprising:
a gate electrode formed on a gate insulation film on a main surface of a semiconductor substrate of a first conductivity type;
source/drain regions formed to sandwich a channel region formed below the gate electrode, the source/drain regions having a structure in which a first semiconductor layer and a second semiconductor layer are stacked in this order, the first semiconductor layer containing a first element and an impurity of a second conductivity type that are for giving strain to the channel region, and containing a second element that is for suppressing a diffusion of the impurity of the second conductivity type, the second semiconductor layer containing the first element and the impurity of the second conductivity type; and
source/drain extension regions adjacent to the channel region, the extension regions extending respectively from the second semiconductor layers.

2. The semiconductor device according to claim 1, wherein a bottom portion the extension regions is formed at a deeper position in the semiconductor substrate than a portion of the extension region that is in contact with the second semiconductor layer.

3. The semiconductor device according to claim 1, wherein the semiconductor substrate is an n-type silicon substrate, the first element is germanium, the impurity is boron, and the second element is carbon.

4. The semiconductor device according to claim 1, wherein the content of the first element in each of the first semiconductor layers and the second semiconductor layers is in a range from 10 to 30 atom %.

5. The semiconductor device according to claim 1, wherein the content of the second element in the first semiconductor layers is larger than 0 atom % and smaller than 1 atom %.

6. The semiconductor device according to claim 3, wherein a bottom portion the extension regions is formed at a deeper position in the semiconductor substrate than a portion of the extension region that is in contact with the second semiconductor layer.

7. The semiconductor device according to claim 3, wherein the content of the first element in each of the first semiconductor layers and the second semiconductor layers is in a range from 10 to 30 atom %.

8. The semiconductor device according to claim 3, wherein the content of the second element in the first semiconductor layers is larger than 0 atom % and smaller than 1 atom %.

9. A method of manufacturing a semiconductor device comprising:
forming a gate electrode on a gate insulation film on a main surface of a semiconductor substrate of a first conductivity type;
forming recessed portions by removing the semiconductor substrate partly at both sides of the gate electrode;
forming source/drain regions by stacking a first semiconductor layer and a second semiconductor layer in this order in each of the recessed portions, the source/drain regions sandwiching the channel region formed below the gate electrode, the first semiconductor layer containing a first element and an impurity of a second conductivity type that are for giving strain to the channel region, and also containing a second element that is for hampering diffusion of the impurity of the second conductivity type, the second semiconductor layer containing the first element and the impurity of the second conductivity type;
forming source/drain extension regions adjacent to the channel region, by diffusing the impurity of the second conductivity type contained in the second semiconductor layers towards the gate electrode through heat treatment on the semiconductor substrate.

10. The method of manufacturing a semiconductor device according to claim 9, wherein
the forming the source/drain regions includes:
making the first semiconductor layers grow selectively to fill the recessed portions;
partly removing the first semiconductor layers to expose upper-side sidewalls of the recessed portions; and
making the second semiconductor layers grow selectively on the first semiconductor layers to fill the recessed portions.

11. The method of manufacturing a semiconductor device according to claim 10, wherein
the forming the source/drain regions includes:
making the first semiconductor layers grow selectively to cover bottom surfaces and sidewalls of the recessed portions;
making the second semiconductor layers grow selectively on the first semiconductor layers to fill the recessed portions;
partly removing the second semiconductor layers to expose the upper-side sidewalls of the recessed portions; and
additionally forming the second semiconductor layers to fill the recessed portions.

12. The method of manufacturing a semiconductor device according to claim 9, wherein the semiconductor substrate is an n-type silicon substrate, the first element is germanium, the impurity is boron, and the second element is carbon.
